(19) United States
(12) Patent Application Publication
(10) Pub. No.: US 2005/0231288 A1
(43) Pub. Date: Oct. 20, 2005

(54) Differential equalizer for broadband communications systems

(76) Inventors: Robert R. Riggsby, Atlanta, GA (US); Walid Kamali, Duluth, GA (US)

Correspondence Address: SCIENTIFIC-ATLANTA, INC.;INTELLECTUAL PROPERTY DEPARTMENT, 5030 SUGARLOAF PARKWAY, LAWRENCEVILLE, GA, 30044, US

(21) Appl. No.: 10/826,737

(22) Filed: Apr. 16, 2004

(51) Int. Cl. H03F 3/191

(52) U.S. Cl. 330/304

(57) ABSTRACT

A device includes a differential equalizer that is suitable for use between an amplification chain. Additionally, the differential equalizer is suitable for use coupled before or after an amplification chain in a transmitter or a receiver. The device comprises a differential equalizer for equalizing an input signal. The differential equalizer can be packaged into an integrated circuit for greater performance figures.

### FIELD OF THE INVENTION

The present invention relates generally to the field of communications system, and more specifically towards an equalizer and an amplification circuit that are included in integrated circuits that are suitable for use in the broadband communications system.

### BACKGROUND OF THE INVENTION

Broadband communications systems include a transmitter that provides signals to a transmission channel, which may be, for example, optical fiber and/or coaxial cables. It is well known that every transmission channel introduces some amount of loss or attenuation so that the signal power progressively decreases with increasing distance. By way of example, inherent in the coaxial cable are losses due to conductor resistances, absorptive losses in the insulating material, and signal leakage between the braids of the outer shield. These losses, for example, are frequency dependent (i.e., there is more loss at higher frequencies). A receiver at an opposite end of the transmission channel receives the transmitted signals and then typically amplifies the signals to compensate for the transmission loss, and typically provides an amplification response shape that is the inverse of the losses.

Furthermore, additional unwanted effects are also introduced to the signal during signal transmission. These unwanted effects, such as distortion, interference, and noise, are serious considerations when designing products that operate in the communications system. More specifically, distortion is caused by an imperfect response of the system to the desired signal itself. Consequently, distortion may become higher when equalizers are placed at the output side of a device. On the other hand, noise, which is random and unpredictable electrical signals produced by internal and external processes in the system, may become excessive when an equalizer is placed at the input of a device. It will be appreciated that the presence of a significant amount of noise may seriously corrupt the signal and reduce its ability for amplification. Filtering reduces noise, but typically noise constitutes a system limitation.

In order to mitigate the effects of distortion and losses while maintaining a suitable level of signal to noise ratio, highly linear transmitters and receivers are typically desired. Equalizers are capable of frequency shaping the loss and potentially improving distortion to tolerable levels. Conventionally, equalizers are designed using discrete components comprised of inductors, capacitors, resistors, diodes, and transistors, to name a few, in order to achieve varying values. The values are chosen based on the distance of the receiver from the transmitter, which is a factor when determining signal loss. The equalizers are then included in a transmitter and/or receiver in order to improve linearity of the signal.

FIG. 1 illustrates two examples of single-ended equalizers that may be placed either before or after an amplification chain depending upon design. It will be appreciated that the amplification chain 105 comprises amplifier stages that are packaged as integrated circuits and installed in a transmitter or receiver as one component; however, the amplifier stages can also be packaged into separate integrated circuits. In the first example 110, the amplification chain 105 receives signals having an input power level. A first and second amplifier stage 115, 120 amplifies the input signal. Subsequently, an equalizer 125 is included after the amplification chain 105 in order to mitigate some of the negative effects of the signal loss caused by the transmission channel. More specifically, the equalizer 125 attempts to correct the tilt of the signal. The tilt can either be an upward or downward tilt, cable, linear, or a combination of cable and linear tile, or also may have a smile or a frown shape, depending on the length of and the loss presented by the transmission cable. Advantageously, as a result of the equalization by the equalizer 125, the output signal is frequency shaped. Unfortunately, however, the equalizer 125 attenuates the output power. Accordingly, the output power level of the signal is lower than the output power level of the signal provided by the amplification chain 105. Additionally, since noise figure has an additive effect, the output signal includes the accumulated noise added throughout the system plus the noise caused by the equalizer 125.

Referring to the second example 130, an input signal having an input power level is first provided to the equalizer 125 that attempts to initially correct for the loss (i.e., the cable tilt) caused by the system. Similarly, the equalizer 125 attenuates the power. The amplification chain 105 then amplifies the signal with the amplifier stages 115, 120 to provide an output signal having an output power level.

The gain and noise figures for the two examples 110, 130, respectively, can be calculated using example values as shown in the following tables. Since the equalizer is frequency dependent, two frequency points are shown.

Example at 50 MHz with a 5 dB up-tilt network as described:

| | Input Power | Gain/ | | | |
|---|---|---|---|---|---|
| | Level | NF | Gain/NF | Gain/NF | Output Power |
| | (dBmV) | (dB) | (dB) | (dB) | Level (dBmV) |
| Example 1 | 0 | 20/5 | 20/5 | −6/6 | 34 |
| Example 2 | 0 | −6/6 | 20/5 | 20/5 | 34 |

Example at 1000 MHz with a 5 dB up-tilt network as described:

| | Input | | | | |
|---|---|---|---|---|---|
| | Power | | | | |
| | Level | Gain/NF | Gain/NF | Gain/NF | Output Power |
| | (dBmV) | (dB) | (dB) | (dB) | Level (dBmV) |
| Example 1 | 0 | 20/5 | 20/5 | −1/1 | 39 |
| Example 2 | 0 | −1/1 | 20/5 | 20/5 | 39 |

The gain and noise figures illustrated above are then linearized in order to add the cumulative effect of the noise through the amplification chain 105 and the equalizer 125. The formulas used for linearizing the gain and noise figure and adding the cumulative effect of the noise are as follows:
Gainₙ=10^{((Gainn(dB)/(10))}
NFₙ=10^{((NFn(dB)/(10))}
NF_{TOT}=NF₁+(NF₂−1)/(Gain₁)+(NF₃−1)/((Gain₂)(Gain_{1)) CSO}ₜₒₜₐₗ=20*Log (10^{\hat{ }(CSO}1^{/20)}+10^{\hat{ }(CSO}2^{/20)}) CTBₜₒₜₐₗ=10*Log (10^{\hat{ }(CTB}1^{/10)}+10^{\hat{ }(CTB}2^{/10)})

The linearized noise figure and the accumulated totals for the two examples 110, 130 are shown in the table below.

Example at 50 MHz with a 5 dB up-tilt network as described:

| | Linearized | Linearized | Linearized | |
|---|---|---|---|---|
| | NF/ | NF/ | NF/ | Linearized |
| | Contribution | Contribution | Contribution | Final NF |
| Example 1 | 3.162278/ | 3.162278/ | 3.981072/ | 3.1842 |
| | 3.162278 | 0.021623 | 0.0003 | |
| Example 2 | 3.981072/ | 3.162278/ | 3.162278/ | 12.6753 |
| | 3.981072 | 3.608182 | 0.0861 | |

Example at 1000 MHz with a 5 dB up-tilt network as described:

| | Linearized | Linearized | Linearized | |
|---|---|---|---|---|
| | NF/ | NF/ | NF/ | Linearized |
| | Contribution | Contribution | Contribution | Final NF |
| Example 1 | 3.162278/ | 3.162278/ | 1.258925/ | 3.1839 |
| | 3.1612278 | 0.021623 | 0.0000 | |
| Example 2 | 1.258925/ | 3.162278/ | 3.162278/ | 4.0083 |
| | 1.258925 | 2.722146 | 0.0272 | |

Example with 5 dB up-tilted network as described

| | CTB/CSO | CTB/CSO | CTB/CSO |
|---|---|---|---|
| | (dBc) | (dBc) | (dBc) |
| Example 1 | 75/75 | 65/65 | NA |
| Example 2 | NA | 80/80 | 70/70 |

The final noise figure (dB) and distortion values (i.e., composite triple beat (CTB) and composite second order (CSO)) can also be calculated using the values above, and are illustrated in the following table:

Example with a 5 dB up-tilt:

Final NF (dB)

| | 50 MHz | 1000 MHz | CTB (dB) | CSO (dB) |
|---|---|---|---|---|
| Example 1 | 5.03 | 5.03 | 65.0 | 62.5 |
| Example 2 | 11.03 | 6.03 | 70.0 | 67.5 |

Notably, the noise figure in Example 2 is worse than the noise figure of Example I due to the placement of the equalizer 125. Interestingly, however, the distortion figures in Example 2 are better than Example 1. As can be seen, output specifications (e.g., output power, distortion levels, and noise figures) need to be understood prior to designing a product. For example, an equalizer may produce better distortion levels, but disadvantageously provide worse noise figures. Therefore, what is needed is an optimum product that is designed for mitigating the effects of the signal loss while maintaining good distortion levels.

### BRIEF DESCRIPTION OF THE DRAWINGS

FIG. 1 illustrates equalizers that may be placed either before or after an amplifier chain depending upon design.

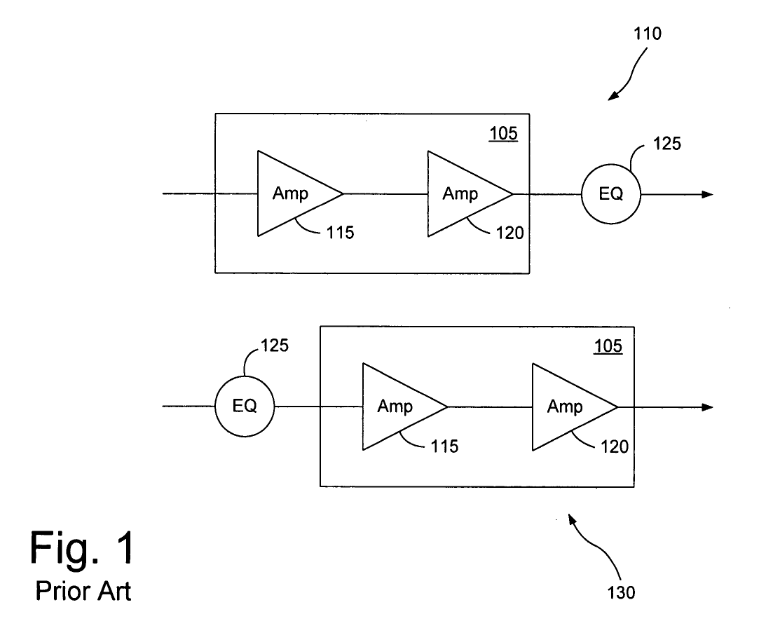

FIG. 2 illustrates a device comprising an equalizer and an amplification chain packaged in an integrated circuit in accordance with the present invention.

FIG. 3 is a schematic of a single-ended up-tilt equalizer in accordance with the present invention.

FIG. 4 is a schematic of a single-ended down-tilt equalizer in accordance with the present invention.

FIG. 5 is a schematic of a differential up-tilt equalizer in accordance with the present invention.

FIG. 6 is a schematic of a differential down-tilt equalizer in accordance with the present invention.

### DETAILED DESCRIPTION OF A PREFERRED EMBODIMENT

The present invention will be described more fully hereinafter with reference to the accompanying drawings in which like numerals represent like elements throughout the several figures, and in which an exemplary embodiment of the invention is shown. This invention may, however, be embodied in many different forms and should not be construed as being limited to the embodiments set forth herein; rather, the embodiments are provided so that this disclosure will be thorough and complete, and will fully convey the scope of the invention to those skilled in the art. The present invention is described more fully hereinbelow.

The present invention is suitable for use in a broadband communications system that requires amplification and equalization of transmitted signals due to loss in the transmission channel. More specifically, the present invention comprises an equalizer and an amplification chain that are included within an integrated circuit. The equalizer may be a fixed value or alternatively it may be a tunable value. Importantly, the present invention does not contribute greatly to the noise figure and has improved distortion levels when compared to conventional equalizers and their placement relative to the amplification chain.

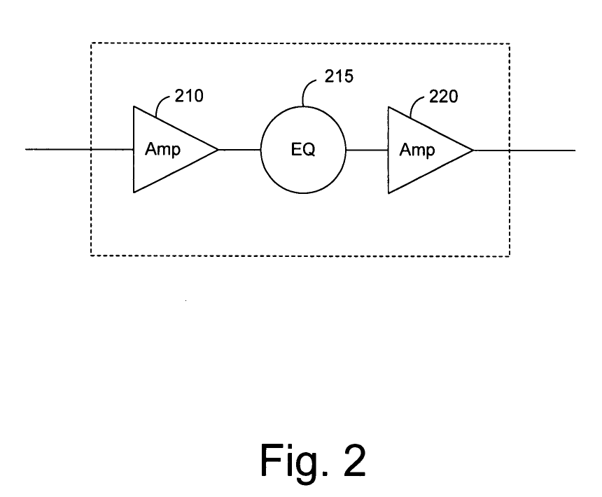

FIG. 2 illustrates a device comprising an equalizer and an amplification chain packaged in an integrated circuit in accordance with the present invention. A signal having an input power level is provided to a first amplification stage 210, which may be included in a transmitting and/or receiving device. An integrated equalizer 215 then corrects for the signal loss, but also attenuates the signal. A second amplification stage 220 then amplifies the signal again to provide a signal having a desired output power level. Using the same values for the amplifier stages 210, 220 and the equalizer as the example values in Examples 1 and 2, the gain and noise figures for the two examples 110, 130, and the present invention, respectively, can be calculated using example values as shown in the following tables.

Example at 50 MHz with a 5 dB up-tilt network:

| | Input | | | | |
|---|---|---|---|---|---|
| | Power | | | | |
| | Level | Gain/NF | Gain/NF | Gain/NF | Output Power |
| | (dBmV) | (dB) | (dB) | (dB) | Level (dBmV) |
| Example 1 | 0 | 20/5 | 20/5 | −6/6 | 34 |
| Example 2 | 0 | −6/6 | 20/5 | 20/5 | 34 |
| Present | 0 | 20/5 | −6/6 | 20/5 | 34 |
| Invention | | | | | |

Example at 1000 MHz with a 5 dB up-tilt network:

| | Input | | | | |
|---|---|---|---|---|---|
| | Power | | | | |
| | Level | Gain/NF | Gain/NF | Gain/NF | Output Power |
| | (dBmV) | (dB) | (dB) | (dB) | Level (dBmV) |
| Example 1 | 0 | 20/5 | 20/5 | −1/1 | 39 |
| Example 2 | 0 | −1/1 | 20/5 | 20/5 | 39 |
| Present | 0 | 20/5 | −1/1 | 20/5 | 39 |
| Invention | | | | | |

The linearized noise figure and the accumulated totals for the two examples 110, 130 and the present invention are shown in the table below.

Example at 50 MHz with a 5 dB up-tilt network:

| | Linearized | Linearized | Linearized | |
|---|---|---|---|---|
| | NF/ | NF/ | NF/ | Linearized |
| | Contribution | Contribution | Contribution | Final NF |
| Example 1 | 3.162278/ | 3.162278/ | 3.981072/ | 3.1842 |
| | 3.162278 | 0.021623 | 0.0003 | |
| Example 2 | 3.981072/ | 3.162278/ | 3.162278/ | 12.6753 |
| | 3.981072 | 8.608182 | 0.0861 | |
| Present | 3.162278/ | 3.981072/ | 3.162278/ | 3.2782 |
| Invention | 3.162278 | 0.029811 | 0.0861 | |

Example at 1000 MHz with a 5 dB up-tilt network:

| | Linearized | Linearized | Linearized | |
|---|---|---|---|---|
| | NF/ | NF/ | NF/ | Linearized |
| | Contribution | Contribution | Contribution | Final NF |
| Example 1 | 3.162278/ | 3.162278/ | 1.258925/ | 3.1839 |
| | 3.162278 | 0.021623 | 0.0000 | |
| Example 2 | 1.258925/ | 3.162278/ | 3.162278/ | 4.0083 |
| | 1.258925 | 2.722146 | 0.0272 | |
| Present | 3.162278/ | 1.258925/ | 3.162278/ | 3.1921 |
| Invention | 3.162278 | 0.002589 | 0.0272 | |

Example with 5 dB up-tilted network as described

| | CTB/CSO | CTB/CSO | CTB/CSO |
|---|---|---|---|
| | (dBc) | (dBc) | (dBc) |
| Example 1 | 75/75 | 65/65 | NA |
| Example 2 | NA | 80/80 | 70/70 |
| Present Invention | 75/75 | NA | 70/70 |

The final noise figure (dB) and distortion values (i.e., composite triple beat (CTB) and composite second order (CSO)) can also be calculated using the values above, and are illustrated in the following table:

Example with a 5 dB up-tilt network:

| | Final NF (dB) | | | |
|---|---|---|---|---|
| | 50 MHz | 1000 MHz | CTB (dB) | CSO (dB) |
| Example 1 | 5.03 | 5.03 | 65.0 | 62.5 |
| Example 2 | 11.03 | 6.03 | 70.0 | 67.5 |
| Present Invention | 5.16 | 5.04 | 69.2 | 66.0 |

Notably, in accordance with the present invention, by placing the equalizer 215 between the amplifier stages 210, 220 and subsequently packaging in an integrated circuit, the distortion and noise figures are noticeably improved. It will be appreciated that the equalizer 215 and amplifier stages 210, 220 can alternatively be individually packaged as an integrated circuit and 15 then placed in the arrangement as shown in FIG. 2.

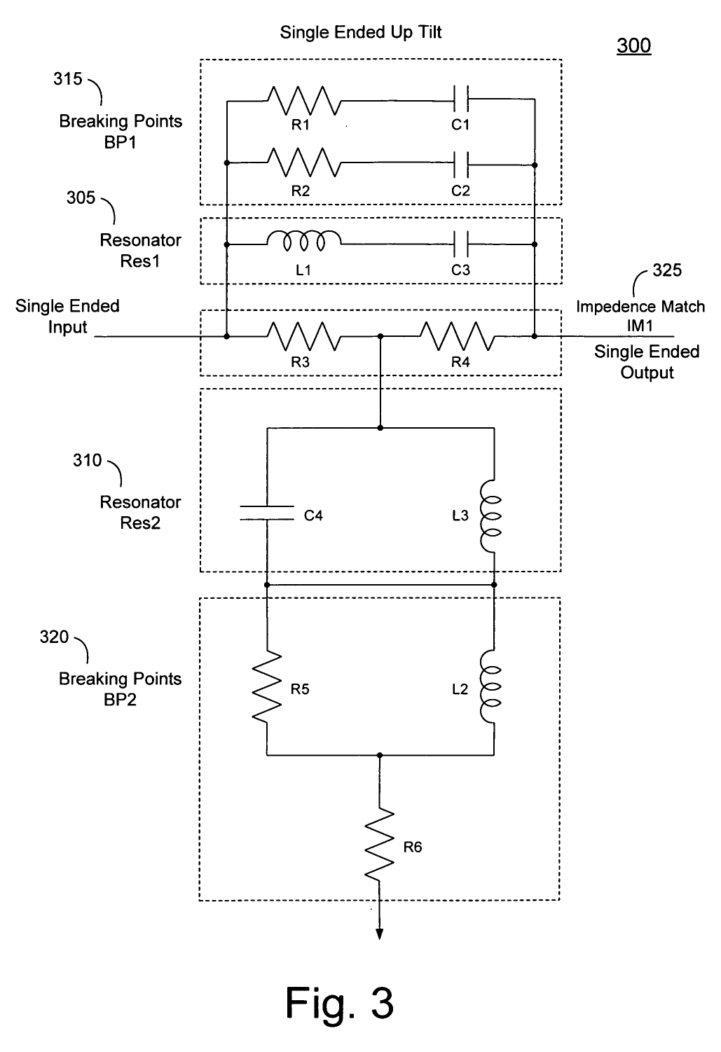

It will be appreciated that the amplifier stages 210, 220 can be either single-ended or differential amplifiers. In the case of single-ended amplifiers 210, 220, a single-ended equalizer having either an up-tilt or a down-tilt, depending upon the design of the system, is placed between the amplifiers 210, 220. FIG. 3 is a schematic of a single-ended up-tilt equalizer 300 in accordance with the present invention. An up-tilt equalizer 300 is used to adjust the signal response upward in frequency since the cable presents losses to the signal. The value of the up-tilt equalizer 300 is such that at the input of the next receiver, the incoming signal is a shape that the system requires (e.g., up-tilt, down-tilt, cable, linear, cable/linear, flat, smile, or frown). Resonators 305, 310 adjust the frequency response of the signal upward to the point that is necessary to adjust for the cable loss. Breakpoints 315, 320 are also in the design for frequency shaping; for example, there may be portions of the signal throughout the frequency band that need leveling. Additionally, an impedance match circuit 325 matches the impedance of the equalizer 300 to the impedance of the cable or the impedance of the amplifier stages.

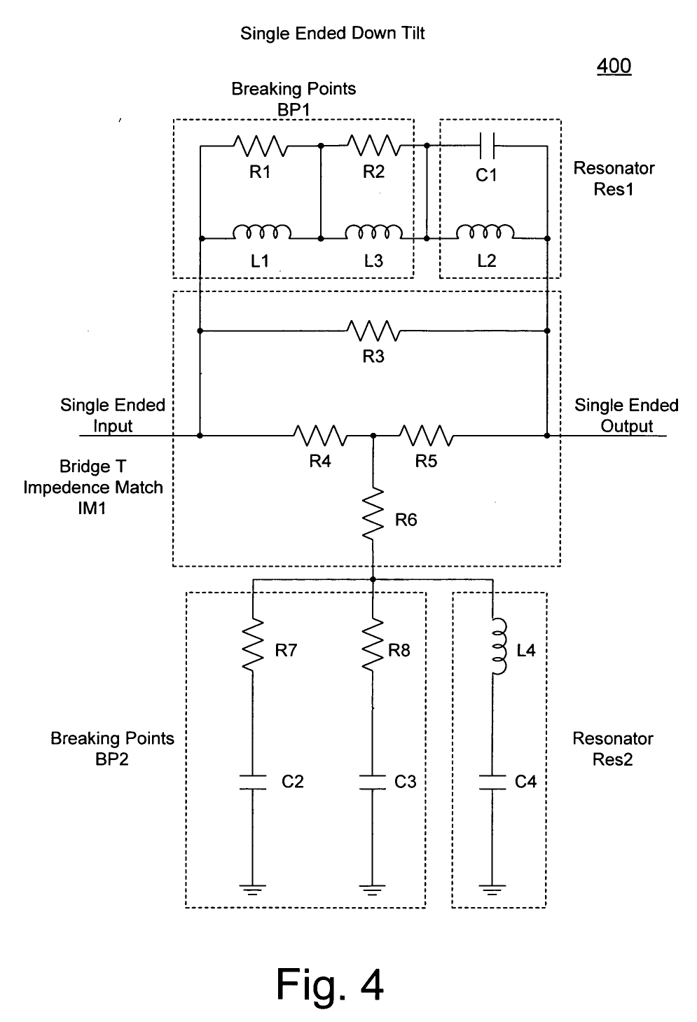

FIG. 4 is a schematic of a single-ended down-tilt equalizer 400 in accordance with the present invention. The down-tilt equalizer 400, which may also be known in the art as a cable simulator, is used in a receiving device when there is not a sufficient length of cable at the input of the transmitting device or the output of the receiving device to sufficiently level an up-tilted signal. The down-tilt equalizer 400 also uses breakpoints, resonators, and an impedance match with values depending on the system design. It will be appreciated that the single-ended equalizers 300, 400 use ground as a reference. Accordingly, the grounding somewhat limits the flexibility in supporting an increased bandwidth.

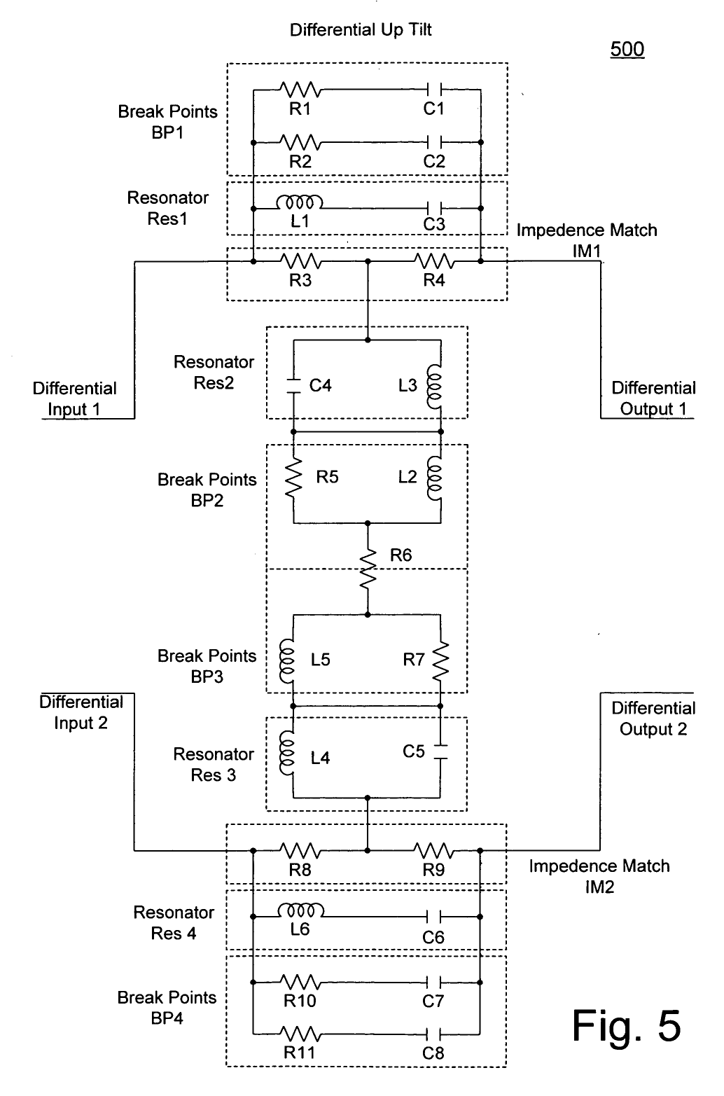

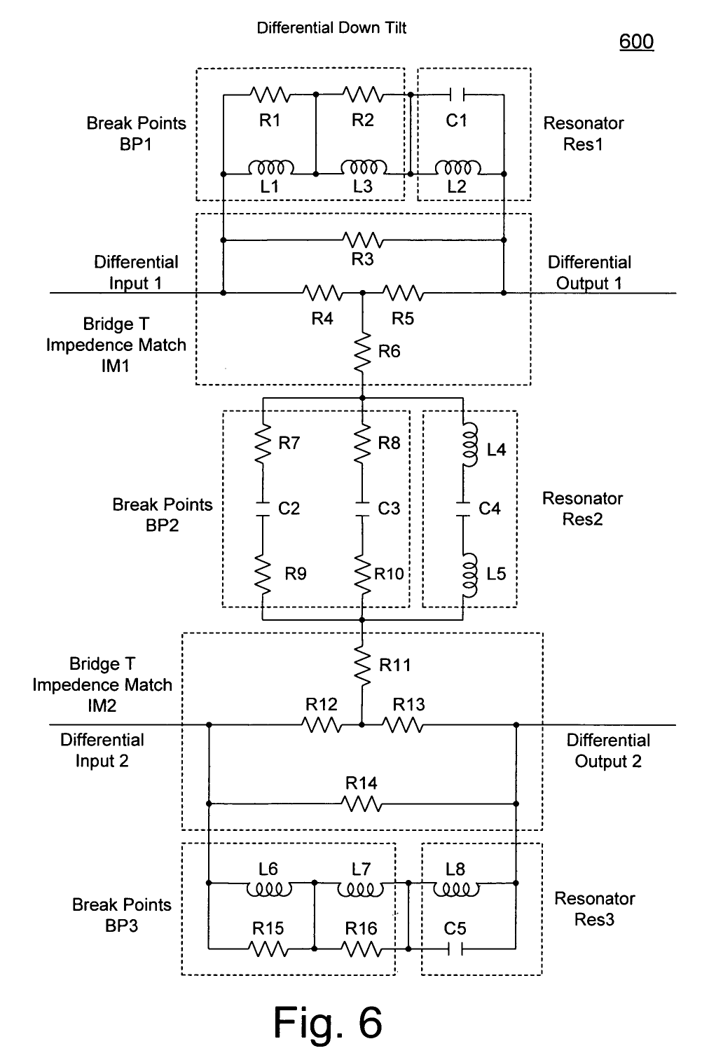

In the case of differential amplifier stages 210, 220, a differential equalizer having either an up-tilt or a down-tilt is placed between the amplifier stages 210, 220. FIGS. 5 and 6 are schematics of a differential up-tilt equalizer 500 and a down-tilt equalizer 600, respectively, in accordance with the present invention. Similar to the single-ended equalizers 300, 400, the differential equalizers have breakpoints, resonators, and impedance match networks with values chosen for an intended value equalizer. Advantageously, the differential equalizers 500, 600 have several advantages when used between or after a differential amplifier stage. A first advantage is that there is symmetry in the differential input and output lines. The differential equalizer 500, 600 designed using integrated circuit technology has balance and symmetry that is required to improve CSO; whereas, conventional component equalizers have too much variance and could potentially unbalance the differential lines in a complex equalizer design. A design with unbalanced differential legs will degrade the CSO performance. Another advantage is the reduced circuit complexity that is achieved by not having to go from a differential output to a single-ended input and then a single-ended output to a differential input. Having a differential equalizer reduces the total part costs and design time. Additionally, a further advantage is that a differential equalizer 500, 600 provides a floating ground in contrast to a single-ended equalizer 300, 400. The floating ground allows an increased bandwidth and lower loss capability. More specifically, the differential lines reference to either signal, not to ground. Furthermore, the parasitics, which may contribute to the loss and distortion, of the design are lessened. Since designs are concerned with losses and are continuously going higher in the frequency range above 1 GHz, to name one example, the ability to equalize over the increased bandwidth while maintaining low losses becomes more important.

It will be appreciated that modifications can be made to the embodiment of the present invention that is still within the scope of the invention. Additionally, the present invention can be implemented using hardware and/or software that are within the scope of one skilled in the art. The embodiments of the description have been presented for clarification purposes; however, the invention is defined by the following claims.

1. A device for equalizing an input signal, comprising:
a differential equalizer coupled to the first differential amplifier stage for frequency shaping the amplified input signal, wherein the differential equalizer comprises a floating ground for increased signal bandwidth.

2. A device for equalizing and amplifying an input signal, comprising:
a first differential amplifier stage for receiving the input signal having an input power level and for amplifying the input signal;
a differential equalizer coupled to the first differential amplifier stage for frequency shaping the amplified input signal, wherein the differential equalizer comprises a floating ground for increased signal bandwidth; and
a second differential amplifier stage coupled to the differential equalizer for further amplifying the input signal to provide an amplified output signal,
wherein the positioning of the differential equalizer between the first and second differential amplifier stages maintains a low level of noise and improved distortion levels.

3. The device of claim 2, wherein a comparison between the noise level of the device are improved over a noise level of a device having a single-ended equalizer positioned prior to amplifier stages.

4. The device of claim 2, wherein a comparison between the distortion levels of the device are improved over distortion levels of a device having a single-ended equalizer positioned subsequent to amplifier stages.

5. The device of claim 2, wherein the first and second differential amplifier stages and the differential equalizer are packaged in an integrated circuit, or wherein the first differential amplifier stage, the second differential stage, and the differential equalizer are packaged as integrated circuits.

6. The device of claim 2, wherein the device is located within a transmitting device.

7. The device of claim 2, wherein the device is located within a receiving device.

8. The device of claim 2, wherein the differential equalizer has a set of fixed value components.

9. The device of claim 2, wherein the differential equalizer has a set of tunable value components.

10. The device of claim 2, wherein the differential equalizer is an up-tilt differential equalizer, the up-tilt differential equalizer comprising:
first and second differential inputs;
first and second differential outputs;
breakpoint circuits coupled between the first and second differential inputs and outputs for frequency shaping the input signal;
resonator circuits coupled between the first and second differential inputs and outputs for adjusting the input signal upward to a predetermined point; and
impedance matching circuits coupled between the first and second differential inputs and outputs for matching impedances of the device to a transmission medium.

11. The device of claim 2, wherein the differential equalizer is a down-tilt differential equalizer, the down-tilt differential equalizer comprising:
first and second differential inputs;
first and second differential outputs;
breakpoint circuits coupled between the first and second differential inputs and outputs for frequency shaping the input signal;
resonator circuits coupled between the first and second differential inputs and outputs for adjusting the input signal downward to a predetermined point; and
impedance matching circuits coupled between the first and second differential inputs and outputs for matching impedances of the device to a transmission medium.

12. A transmitting device for transmitting a signal having a particular frequency response, the transmitting device comprising:
an input for receiving an input signal having an input power level;
a device for amplifying and equalizing the input signal, the device comprising:
a first differential amplifier stage for receiving the input signal and for amplifying the input signal;
a differential equalizer coupled to the first differential amplifier stage for equalizing the amplified input signal; and
a second differential amplifier stage coupled to the differential equalizer for further amplifying the input signal to provide an amplified output signal,
whereby the positioning of the differential equalizer between the first and second differential amplifier stages maintains a low level of noise and improved distortion levels.

13. The device of claim 12, wherein a comparison between the noise level of the device are improved over a noise level of a device having a single-ended equalizer positioned prior to amplifier stages.

14. The device of claim 12, wherein a comparison between the distortion levels of the device are improved over distortion levels of a device having a single-ended equalizer positioned subsequent to amplifier stages.

15. The transmitting device of claim 12, wherein the differential equalizer provides the output signal having a frequency response that is tilted up.

16. The transmitting device of claim 12, wherein the differential equalizer provides the output signal having a frequency response that is one of tilted down, cable shaped, linear shaped, a combination of cable and linear shaped, a frown, and a smile.

17. A receiving device for receiving an input signal and providing an output signal having a particular frequency response, the receiving device comprising:
an input for receiving an input signal having an input power level;
a device for amplifying and equalizing the input signal, the device comprising:
a first differential amplifier stage for receiving the input signal and for amplifying the input signal;
a differential equalizer coupled to the first differential amplifier stage for equalizing the amplified input signal; and
a second differential amplifier stage coupled to the differential equalizer for further amplifying the input signal to provide an amplified output signal,
whereby the positioning of the differential equalizer between the first and second differential amplifier stages maintains a low level of noise and improved distortion levels.

18. The device of claim 17, wherein a comparison between the noise level of the device are improved over a noise level of a device having a single-ended equalizer positioned prior to amplifier stages.

19. The device of claim 17, wherein a comparison between the distortion levels of the device are improved over distortion levels of a device having a single-ended equalizer positioned subsequent to amplifier stages.
